(19) United States
(12) Patent Application Publication
(10) Pub. No.: US 2026/0369309 A1
(43) Pub. Date: Nov. 19, 2026

(54) MEMORY CIRCUIT AND DRIVING METHOD THEREOF

(71) Applicant: Kwangwoon University Industry-Academic Collaboration Foundation, Seoul (KR)

(72) Inventors: Chanheum HAN, Seoul (KR); Juncheol LEE, Seoul (KR); Joo-Hyung CHAE, Seoul (KR)

(73) Assignee: Kwangwoon University Industry-Academic Collaboration Foundation, Seoul (KR)

(21) Appl. No.: 19/286,927

(22) Filed: Jul. 31, 2025

(30) Foreign Application Priority Data
May 19, 2025 (KR) 10-2025-0064727

(51) Int. Cl. G11C 5/14; G11C 5/06; G11C 11/4091; G11C 11/4093; G11C 11/4096

(52) U.S. Cl. CPC G11C 5/147; G11C 5/06; G11C 11/4091; G11C 11/4093; G11C 11/4096

(57) ABSTRACT

Provided are a memory circuit and a driving method thereof. More particularly, the memory circuit includes a memory cell, an interface, and a bus circuit connecting the memory cell and the interface, wherein the bus circuit includes a receiving terminal and a transmitting terminal, the receiving terminal includes a level shifter including a capacitor and a positive-channel metal-oxide semiconductor (PMOS), and a trans-impedance amplifier (TIA), wherein the level shifter decreases a supply voltage of the transmitting terminal to below a reference voltage by outputting a first voltage that is set according to a size of at least one transistor included in the TIA by turning off the PMOS in a first mode and outputting a second voltage set according to a current introduced from the TIA by turning on the PMOS in a second mode.

### CROSS-REFERENCE TO RELATED APPLICATION

This application is based on and claims priority under 35 U.S.C. § 119 to Korean Patent Application No. 10-2025-0064727, filed on May 19, 2025, in the Korean Intellectual Property Office, the disclosure of which is incorporated by reference herein in its entirety.

### BACKGROUND

### 1. Field

The disclosure relates to a memory circuit and a driving method thereof. More particularly, the disclosure relates to a technology of providing a minimalized transceiver including a Trans-impedance Amplifier (TIA) in which an end portion of a level shifter is utilized.

This research has been conducted under support of Samsung Research & Incubation Center for Future Technology (Project Number: SRFC-IT2401-06).

### 2. Description of the Related Art

A memory circuit may be configured to transceive various signals. A memory circuit may include channels configured to transceive various signals. Each of the channels in the memory circuit may include a transmitting terminal configured to transmit signals and a receiving terminal configured to receive the signals. Characteristics of transceiving the signals may be determined by characteristic impedance of each of the transmitting terminal and the receiving terminal of the channel.

The memory circuit may include a trans-impedance amplifier (TIA). The TIA may be connected to the receiving terminal of the channel in the memory circuit. The TIA may be configured to adjust the characteristic impedance of the channel.

Various types of circuit structures have been suggested to further improve the performance of transceiving signals by the memory circuit including the TIA. For example, there has been suggested a circuit structure in which the TIA of the memory circuit is designed with a regulated cascode (RGC) structure to increase bandwidth. As another example, a circuit structure in which a dicode encoder is applied to the TIA of the memory circuit to reduce consumption of static current has been suggested.

However, when an RGC structure is applied, the reference voltage (VDD) is maintained at a high level, making it difficult to apply to recent memory circuits in which low-level supply voltages are used. In addition, when a dicode encoder is applied, additional circuits such as a decoder, a driver, an error correction circuit may be required, and thus the structure of the circuit may become more complex. Therefore, there has been demand for a solution to further improve the performance of the memory circuit to transceive the signals while using a low-level supply voltage and maintaining a simple structure of the circuit.

### SUMMARY

Additional aspects will be set forth in part in the description which follows and, in part, will be apparent from the description, or may be learned by practice of the presented embodiments of the disclosure.

According to an aspect of the disclosure, a memory circuit may include a memory cell; an interface; and a bus circuit connecting the memory cell and the interface to each other, wherein the bus circuit may include a receiving terminal; and a transmitting terminal, the receiving terminal may include a level shifter including a capacitor and a positive-channel metal-oxide semiconductor (PMOS), and a trans-impedance amplifier (TIA), wherein the level shifter may decrease a supply voltage of the transmitting terminal to below a reference voltage by outputting a first voltage that is set based on a size of at least one transistor included in the TIA by turning off the PMOS in a first mode and outputting a second voltage set according to a current introduced from the TIA by turning on the PMOS in a second mode.

According to another aspect of the disclosure, a driving method of a memory circuit the memory circuit including a memory cell, an interface, and a bus circuit connecting the memory cell and the interface, wherein the bus circuit may include a receiving terminal and a transmitting terminal, wherein the transmitting terminal may include a level shifter and a positive-channel metal-oxide semiconductor (PMOS), and a trans-impedance amplifier (TIA) and wherein the level shifter may include a capacitor and a positive-channel metal-oxide semiconductor (PMOS), the method may include decreasing, by the level shifter, a supply voltage of the transmitting terminal to below a reference voltage by outputting a first voltage set according to a size of at least one transistor included in the TIA by turning off the PMOS in a first mode and outputting a second voltage set according to a current introduced from the TIA by turning on the PMOS in a second mode and.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating a memory circuit according to an embodiment;

FIG. 2 is a table indicating preferred impedance according to termination circuit types included in the memory circuit and advantages and disadvantages of the impedance;

FIG. 3 is a diagram illustrating a driving type of a trans-impedance amplifier (TIA);

FIG. 4 is a circuit diagram illustrating a bus circuit according to an embodiment;

FIG. 5A is a diagram illustrating a driving type of a transmitting terminal according to an embodiment;

FIG. 5B is a diagram illustrating a driving type of a transmitting terminal according to an embodiment;

FIG. 6 is a diagram illustrating a driving type of a transmitting terminal according to an embodiment;

FIG. 7 is a diagram illustrating a driving type of a bus circuit according to an embodiment;

FIG. 8 is a diagram illustrating a driving type of a bus circuit according to an embodiment;

FIG. 9 is a diagram illustrating a driving type of a bus circuit according to an embodiment; and

FIG. 10 is a diagram illustrating a type of application of a memory circuit according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Various embodiments of the present document and terms used herein are not intended to limit technical features written herein to certain embodiments, and will be understood as including various modifications, equivalents, or substitutes of corresponding embodiments.

Regarding descriptions of the drawings, similar reference numerals may be used for similar or relevant components.

Unless clearly indicated otherwise in relevant texts, a singular form of a noun corresponding to an item may include the item or a plurality of the items.

In the present document, expressions such as “A or B”, “at least one of A and B”, “at least one of A or B”, “A, B, or C”, “at least one of A, B, and C” may include any one of items listed in corresponding expressions among the expressions, or any possible combinations thereof.

Terms such as “and/or” include combinations of a plurality of relevant components written herein or any components among the plurality of relevant components written herein.

Terms such as “first” and “second” may be used only to distinguish a corresponding component from other corresponding components, and are not intended to limit the corresponding components in other aspects (e.g.: importance or an order).

When a certain (e.g.: first) component is mentioned as being “coupled” or “connected” to another (e.g.: second) component with or without terms such as “functionally” or “communicatively”, this indicates that the certain component may be connected to the other component directly (e.g.: in a wired manner), in a wireless manner, or through a third component.

Terms such as “comprise” or “include” is to designate presence of features, numbers, steps, operations, components, members written in the present document or combinations thereof, but are not to preclude the possibility of existence or addition of one or more other features, numbers, steps, operations, components, members or combinations thereof.

When it is mentioned that a certain component is “connected to”, “coupled to”, “supported by”, or “in contact with” another component, this includes cases in which components are indirectly connected to, coupled to, supported by or in contact with each other through a third component, as well as cases in which the components are directly connected to, coupled to, supported by, or in contact with each other.

When it is mentioned that a component is located “on” another component, this includes a case in which a third component exists between the component and the other component, as well as a case in which the component is in contact with the other component.

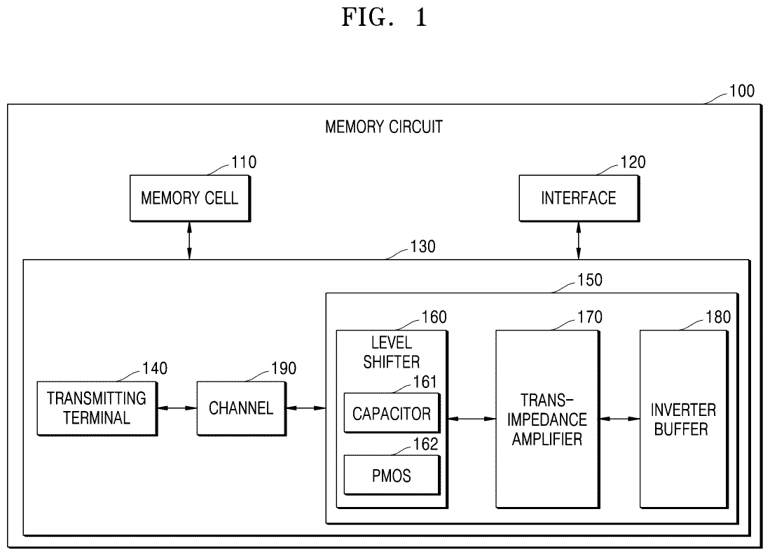

FIG. 1 is a block diagram illustrating a memory circuit 100 according to an embodiment. The memory circuit 100 may include a circuit included in a memory (e.g., dynamic random access memory (DRAM)) of an electronic device (e.g., a computer, a notebook computer, a tablet PC, a smartphone, a database, a server, and the like) or a circuit connecting the memory and other components in the electronic device. The memory circuit 100 according to an embodiment may include a memory cell 110, an interface 120, and a bus circuit 130.

The memory cell 110 may include a space for storing data in a memory of an electronic device. The memory cell 110 may include a storage for the memory. The memory cell 110 may include a single memory chip. For example, the memory cell 110 may include a plurality of unit cells. The memory cell 110 may be connected to the interface 120 through the bus circuit 130.

The interface 120 may include an input terminal or an output terminal of the memory circuit 100. The interface 120 may be connected to the memory cell 110 through the bus circuit 130. Data included in a signal input to the memory circuit 100 may be stored in the memory cell 110. The interface 120 may be configured to deliver the signal including information, which is stored in the memory cell 110, to another component of the electronic device.

The bus circuit 130 may connect the memory cell 110 and the interface 120. The bus circuit 130 may include a circuit configured to deliver signals. The bus circuit 130 may be configured to deliver the signal, which is received from the interface 120, to the memory cell 110 and store data included in the signal in the memory cell 110. The bus circuit 130 may be configured to receive the signal including the data, which is stored in the memory cell 110, from the memory cell 110 and deliver the signal to the interface 120, such that the interface 120 may output the signal to another component of the electronic device. The bus amplifier 130 may be configured to amplify the signal or filter at least some of frequency components included in the signal. The bus circuit 130 may include components for improving performance of delivering the signal. The bus circuit 130 may include a transmitting terminal 140, a receiving terminal 150, and an RC-dominant channel 190. The receiving terminal 150 may include a level shifter 160, a trans-impedance amplifier (TIA) 170, and an inverter buffer 180.

The transmitting terminal 140 may be configured to enable the bus circuit 130 to transmit the signal. The transmitting terminal 140 may include a circuit configured to output the signal.

The receiving terminal 150 may be configured to enable the bus circuit 130 to receive the signal. The receiving terminal 150 may include a circuit configured to receive the signal.

The channel 190 is a medium for delivering the signal between the transmitting terminal 140 and the receiving terminal 150. The channel 190, i.e., a combination of a resistor and a capacitor, may function like a low-pass filter (LPF).

The level shifter 160 may be connected to the transmitting terminal 140. The level shifter 160 may be configured to change a voltage level of the signal delivered from the transmitting terminal 140. The level shifter 160 may be configured to output, from the receiving terminal 150, the signal having the changed voltage level.

The TIA 170 may be connected to the level shifter 160. The TIA 170 may be configured to amplify the signal delivered from the level shifter 160.

The TIA 170 may be configured to deliver the amplified signal to the inverter buffer 180.

The level shifter 160 may include a capacitor 161 and a positive type metal-oxide semiconductor field-effect transistor (MOSFET) (PMOS) 162. The capacitor 161 may be configured to store or discharge energy to change the voltage level of the signal from the level shifter 160. When turned off, the PMOS 162 may block flow of a current flowing through the level shifter 160. When turned on, the PMOS 162 may allow the flow of the current flowing through the level shifter 160. The PMOS 162 may be configured to control the form of change in the voltage level of the signal by blocking or allowing the flow of the current flowing in the level shifter 160.

The level shifter 160 may output a first voltage set according to a size of at least one transistor included in the TIA 170 by turning off the PMOS 162 in a first mode. The level shifter 160 may output a second voltage set according to a current introduced from the TIA 170 by turning on the PMOS 162 in a second mode. The level shifter 160 may be configured to decrease a supply voltage of the transmitting terminal 140 below a reference voltage.

The memory circuit 100 according to an embodiment may include the level shifter 160 configured to decrease the supply voltage of the transmitting terminal 140 below than the reference voltage. According to an embodiment, a supply voltage at a low level may be used. According to an embodiment, a structure of the memory circuit 100 may be maintained simple. According to an embodiment, the performance of the memory circuit 100 to transceive the signal may be improved.

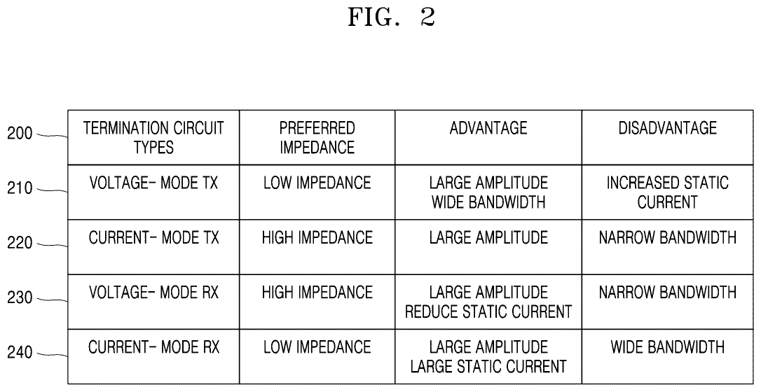

FIG. 2 is a table indicating preferred impedance according to termination circuit types 200 included in the memory circuit 100 and advantages and disadvantages of the impedance.

The memory circuit 100 according to an embodiment may be used for RC dominant channels among wireline channels. Termination circuits having same characteristics as the termination circuit types 200 may be connected to the RC-dominant channels.

An LC (Inductor-capacitor) dominant channel may maintain characteristic impedance of 50Ω regardless of frequency. Unlike this, the RC-dominant channel may have high characteristic impedance at a low frequency and have low characteristic impedance at a high frequency. Accordingly, the RC-dominant channel may function as a low-pass filter (LPF).

The RC-dominant channel has a feature that the characteristic impedance changes according to change in a frequency, and therefore, to reduce reflection of undesired signals, may set RX output impedance and TX input impedance in a direction in which a bandwidth increases.

Preferred impedance according to the termination circuit types 200 may be arranged as in the table shown in FIG. 2. The termination circuit types 200 may include a voltage-mode TX 210, a current-mode TX 220, a voltage-mode RX, and a current-mode RX 240.

The voltage-mode TX 210 may have low impedance. The voltage-mode TX 210 may have a large amplitude and a wide bandwidth. The voltage-mode TX 210 may have an increased static current.

The current-mode TX 220 may have high impedance. The current-mode TX 220 may have a large amplitude. The current-mode TX 220 may have a narrow bandwidth.

The voltage-mode RX 230 may have high impedance. The voltage-mode RX 230 may have a large amplitude and a reduced static current. The voltage-mode RX 230 may have a small bandwidth.

The current-mode RX 240 may have low impedance. The current-mode RX 240 may have a large amplitude and a high static current. The current-mode RX 240 may have a large bandwidth.

To sum up the contents in FIG. 2, a basic trade-off relationship may occur for each of the termination circuit types 200. It is not easy to design termination circuits such that all of bandwidths, amplitudes, and static currents are improved. To overcome such shortcomings, a circuit structure by which input impedance and output impedance may be separately controlled is required.

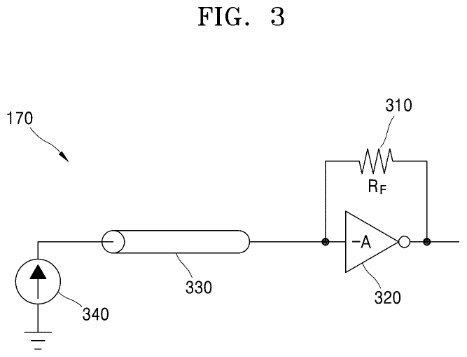

FIG. 3 is a diagram illustrating a driving type of the TIA 170. The TIA 170 may include a resistor 310 and an inverter 320.

The resistor 310 may be arranged in parallel to the inverter 320. The resistor 310 may receive a current from a current source 340 through a channel 330.

As seen from an input side of the inverter 320, a small-signal input impedance R_{IN} may be set based on a magnitude of the resistor 310 and a voltage gain (−A) of the inverter 320. For example, the small-signal input impedance may be calculated as R_{F}/(1+A).

An output trans-impedance gain R_{F} of the TIA 170 may be set according to the magnitude of the resistor 310.

The channel 330 may include an on-chip channel.

When the TIA 170 as illustrated in FIG. 3 is applied to a receiving terminal (e.g.: the receiving terminal 150 in FIG. 1), a basic trade-off relationship between signal processing in a voltage mode (VM) and signal processing in a current mode (CM), which is described with reference to FIG. 2, may be overcome. When the TIA 170 is applied to the receiving terminal, an output trans-impedance gain R_{GAIN} may be increased at the same time when a small-signal input impedance R_{L} is reduced. Accordingly, when the TIA 170 is applied to the receiving terminal, a wide bandwidth and a large amplitude may be both fulfilled. An issue of static current consumption exists in the transmitting terminal at which the current source is used.

For such cases where the TIA 170 is applied, various types of circuit structures have been suggested to further improve the performance of transceiving the signal by the memory circuit 100 including the TIA 170. For example, there is suggested a circuit structure having an increased bandwidth by designing the TIA 170 of the memory circuit 100 in a regulated cascode (RGC) structure. As another example, there is suggested a circuit structure in which the TIA 170 of the memory circuit 100 is designed in an inverter structure and a static current consumption is reduced by applying a di-code encoder to take care of the issue of the static current consumption in the transmitter in which the current source is used.

However, due to a stack structure including a cascode transistor and a current source on an input transistor, the RGC structure requires a sufficient operation headroom, and accordingly, operations may be stably performed only when the reference voltage (VDD) is maintained at a certain level or higher. Accordingly, there is limitation in application to an application circuit in which a low-level supply voltage is used, like the memory circuit 100 which requires a low-voltage driving environment. In addition, when the di-code encoder is applied, additional circuits such as a decoder, a driver, an error correction circuit may be required, and therefore, a structure of the circuit may be complicated. Therefore, there have been demands for a solution to further improve the performance of the memory circuit 100 to transceiver the signal while using a low-level supply voltage and maintaining a simple circuit structure.

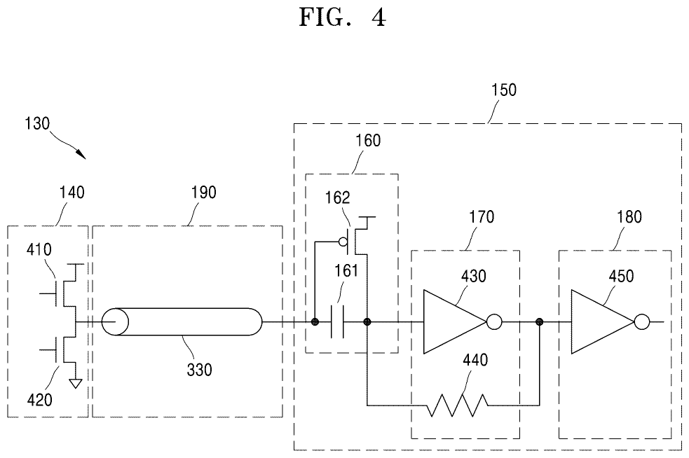

FIG. 4 is a circuit diagram of the bus circuit 130 according to an embodiment. The bus circuit 130 according to an embodiment may include the transmitting terminal 140, a RC-dominant channel 190, and the receiving terminal 150.

The transmitting terminal 140 may include a first transistor 410 and a second transistor 420. A drain electrode of the first transistor 410 may be connected to a supply voltage terminal. A source electrode of the first transistor 410 may be connected to the second transistor 420. A drain electrode of the second transistor 420 may be connected to the first transistor 410. A source electrode of the second transistor 420 may be connected to the ground.

The first transistor 410 and the second transistor 420 may be turned on or turned off according to a level of a signal applied to gate electrodes thereof. The first transistor 410 and the second transistor 420 may be turned on when a high (H)-level signal is applied to the gate electrodes thereof. The first transistor 410 and the second transistor 420 may be turned off when a low (L)-level signal is applied to the gate electrodes thereof.

An end of the RC-dominant channel 190 may be connected to a point at which the first transistor 410 and the second transistor 420 are connected to each other. The other end of the RC-dominant channel 190 may be connected to a point at which the PMOS 162 and the capacitor 161 are connected to each other.

The receiving terminal 150 may include the level shifter 160, the TIA 170, and the inverter buffer 180.

The level shifter 160 may include the capacitor 161 and the PMOS 162. A first electrode of the capacitor 161 may be connected to the RC-dominant channel 190. A second electrode of the capacitor 161 may be connected to the TIA 170. A source electrode of the PMOS 162 may be connected to a supply voltage terminal. A gate electrode of the PMOS 162 may be connected to the first electrode of the capacitor 161. A drain electrode of the PMOS 162 may be connected to the second electrode of the capacitor 161.

The TIA 170 may include an inverter 430 and a resistor 440. An end of the resistor may be connected to a point at which the drain electrode of the PMOS 162 and the second electrode of the capacitor 161 are connected to each other. The other end of the resistor may be connected to a point at which the inverter 430 and an input terminal of the inverter buffer 180 are connected to each other.

The inverter buffer 180 may include a plurality of inverters. The inverter buffer 180 may be connected to the TIA 170. An input terminal of the inverter buffer 180 may be connected to the TIA 170, and an output terminal of the inverter buffer 180 may be connected to another component of a memory circuit (e.g., the memory circuit 100 illustrated in FIG. 1).

The bus circuit 130 according to an embodiment may replace the current-mode TX 220 to the voltage-mode TX 210 by simple circuit structure by using the level shifter 160 including the capacitor 161 and the PMOS 162, therefore the TIA 170 may be used as a termination circuit while removing the static current of the transmitting terminal. The bus circuit 130 according to an embodiment, in which the TIA 170 based on the inverter is used, may ease a matter of voltage headroom, unlike the RGC structure, and thus may be suitable for the memory circuit 100 having a low supply voltage. Unlike in a case where the di-code encoder is applied, the bus circuit 130 according to an embodiment, to which the level shifter 160 is applied, may reduce current consumption of the transmitting terminal 140 in a continuous data pattern while maintaining simple structures of the transmitting terminal 140 and the receiving terminal 150. Accordingly, the bus circuit 130 according to an embodiment may be configured to reduce a supply voltage VDDQ of the transmitting terminal 140 to be lower than the reference voltage VDD. For example, the bus circuit 130 according to an embodiment may reduce a level of the supply voltage VDDQ to 0.5 times the level of the reference voltage VDD of the transmitting terminal 140 or lower, and thus may reduce power consumption of the memory circuit 100.

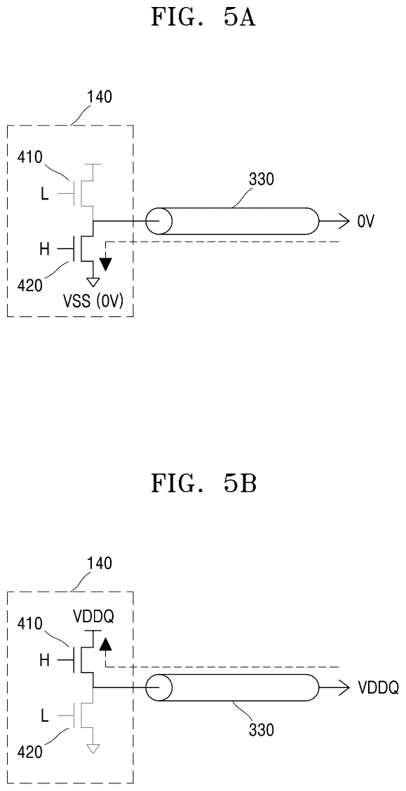

FIG. 5A is a diagram illustrating a driving type of the transmitting terminal 140 according to an embodiment.

A signal at the low level may be applied to the gate electrode of the first transistor 410 of the transmitting terminal 140 connected to the RC-dominant channel 190 according to an embodiment. A signal at the high level may be applied to the gate electrode of the second transistor 420 of the transmitting terminal 140 connected to the RC-dominant channel 190 according to an embodiment. In this case, the first transistor 410 may be turned off, and the second transistor 420 may be turned on. Accordingly, a first path connected to a ground VSS of the transmitting terminal 140 may be activated. The ground VSS may have a ground voltage (0V).

When the first path connected to the ground VSS of the transmitting terminal 140 is activated, the RC-dominant channel 190 according to an embodiment may output the ground voltage (0V). A bus circuit (e.g., the bus circuit 130 illustrated in FIG. 4) according to an embodiment may turn on the second transistor 420, deliver the ground voltage (0V), and deliver the signal at the L level to a level shifter (e.g., the level shifter 160 illustrated in FIG. 4.

FIG. 5B is a diagram illustrating a driving type of the transmitting terminal 140 according to an embodiment.

A signal at the high level may be applied to the gate electrode of the first transistor 410 of the transmitting terminal 140 connected to the RC-dominant channel 190 according to an embodiment. A signal at the low level may be applied to the gate electrode of the second transistor 420 of the transmitting terminal 140 connected to the RC-dominant channel 190. In this case, the first transistor 410 may be turned on, and the second transistor 420 may be turned off. Accordingly, a second path connected to the supply voltage terminal of the transmitting terminal 140 may be activated. The supply voltage terminal may have the supply voltage VDDQ.

When the second path connected to the supply voltage terminal connected to the transmitting terminal 140 is activated, the RC-dominant channel 190 according to an embodiment may output the supply voltage VDDQ. A bus circuit (e.g. the bus circuit 130 illustrated in FIG. 4) may turn on the first transistor 410, deliver the supply voltage VDDQ, and deliver the signal at H level to a level shifter (e.g., the level shifter 160 illustrated in FIG. 4).

Referring to FIGS. 5A and 5B, the transmitting terminal 140 may be configured to transmit signals at different levels to the level shifter 160 through the RC-dominant channel 190. Due to the capacitor 161 of the level shifter 160, current may not flow toward the receiving terminal 150 regarding continuous data. Accordingly, when there is change in the level of the signal delivered from the transmitting terminal 140 to the level shifter 160, the bus circuit 130 according to an embodiment may detect the change in the TIA 170 and, based on the change, output the signal from the inverter buffer 180.

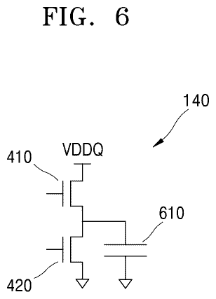

FIG. 6 is a diagram illustrating a driving type of the transmitting terminal 140 according to an embodiment.

Parasitic capacitance (Cₚₐᵣ) 610 may be formed at the transmitting terminal 140. The parasitic capacitance 610 may be formed between the ground and a point at which the first transistor 410 and the second transistor 420 included in the transmitting terminal 140 are connected to each other.

Power consumption of the transmitting terminal 140 of a bus circuit (e.g., the bus circuit 130 illustrated in FIG. 4) according to an embodiment may be referred to as dynamic power. The dynamic power of the transmitting terminal 140 may be determined according to the magnitude (Cₚₐᵣ) of the parasitic capacitance 610 and the level of the supply voltage VDDQ. For example, the dynamic power of the transmitting terminal 140 may be calculated as 0.5*Cₚₐᵣ*VDDQ².

The transmitting terminal 140 according to an embodiment may have a simple structure and thus may reduce the magnitude (Cₚₐᵣ) of the parasitic capacitance 610. Accordingly, the transmitting terminal 140 according to an embodiment may reduce the magnitude of the dynamic power.

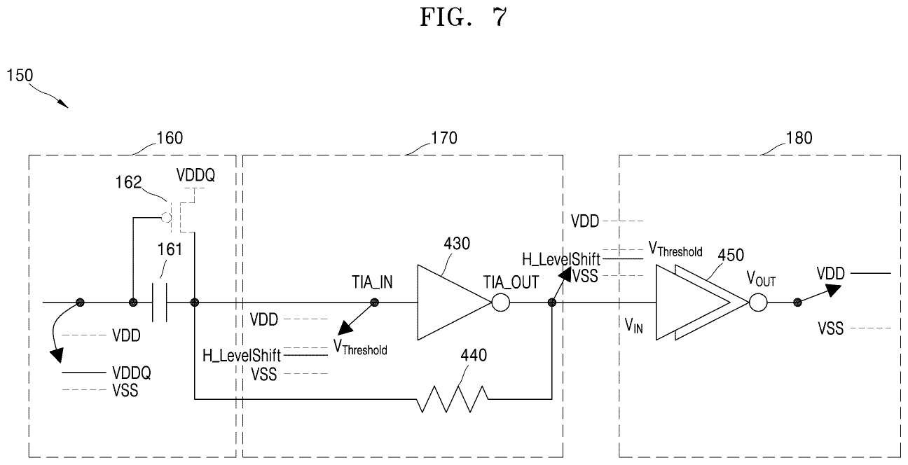

FIG. 7 is a diagram illustrating a driving type of a bus circuit (e.g., the bus circuit 130 illustrated in FIG. 4) according to an embodiment.

In the bus circuit 130 according to an embodiment, when the supply voltage VDDQ at a level lower than the level of the reference voltage VDD is applied, the level shifter 160 may output a high-level shift voltage H_LevelShift. When the supply voltage VDDQ at the level lower than the level of the reference voltage VDD is applied to the level shifter 160, the receiving terminal 150 may output the reference voltage VDD.

The supply voltage VDDQ may be applied to an end of the capacitor 161 and the gate electrode of the PMOS 162 in the level shifter 160. When the supply voltage VDDQ is applied to the gate electrode of the PMOS 162, a voltage level of the source electrode and a voltage level of the gate electrode of the PMOS 162 may be equal to each other. When the voltage level of the source electrode and the voltage level of the gate electrode of the PMOS 162 are equal to each other, the PMOS 162 may be turned off. When the PMOS 162 is turned off, the level shifter 160 may set a voltage of a TIA input node TIA_IN as the high-level shift voltage H_LevelShift lower than a threshold voltage V_{Threshold}. The TIA input node TIA_IN may be located between the other end of the capacitor 161 and an input terminal of the TIA 170 of the receiving terminal 150. The level shifter 160 may output the high-level shift voltage H_LevelShift lower than the threshold voltage V_{Threshold} that has been set.

The TIA 170 may set a voltage of an TIA output node TIA_OUT as the high-level shift voltage H_LevelShift. The TIA output node TIA_OUT may be arranged between a first inverter 430 and a second inverter 450 that is included in the inverter buffer 180. The second inverter 450 may receive the voltage of the TIA output node TIA_OUT as an input voltage V_{IN}. The second inverter 450 may output the reference voltage VDD as an output voltage V_{OUT}.

When the supply voltage VDDQ is applied to the level shifter 160 of the bus circuit 130 according to an embodiment, the PMOS 162 may be turned off and be in a self-bias state. The threshold voltage V_{Threshold} of the TIA input node TIA_IN may be maintained as a certain value according to a ratio between physical sizes of a positive-channel metal-oxide semiconductor (PMOS) and a negative-channel metal-oxide semiconductor (NMOS) of the first inverter 430 included in the TIA 170.

In the bus circuit 130 according to an embodiment, sizes of the transistors (i.e., the first transistor 410 and the second transistor 420) of the transmitting terminal 140 may be set greater than the size of the PMOS 162. In the self-bias state of the TIA 170, the bus circuit 130 according to an embodiment may set the voltages of the TIA-input node TIA_IN and the TIA-output node TIA_OUT lower than the threshold voltage V_{Threshold} of the second inverter 450. Accordingly, the bus circuit 130 according to an embodiment may output the reference voltage VDD as the output voltage VOUT by using a large gain obtained by the TIA 170 and the second inverter 450.

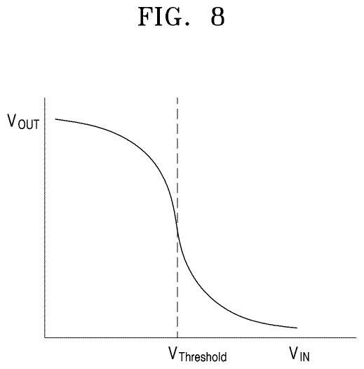

FIG. 8 is a diagram illustrating a driving type of a bus circuit (e.g., the bus circuit 130 illustrated in FIG. 4) according to an embodiment.

The input voltage V_{IN} and the output voltage V_{OUT} of the second inverter 450 of the bus circuit 130 may be in inverse proportion. When the input voltage V_{IN} increases, the output voltage V_{OUT} may decrease. When the input voltage V_{IN} changes, the output voltage V_{OUT} may rapidly change with reference to the threshold voltage V_{Threshold}.

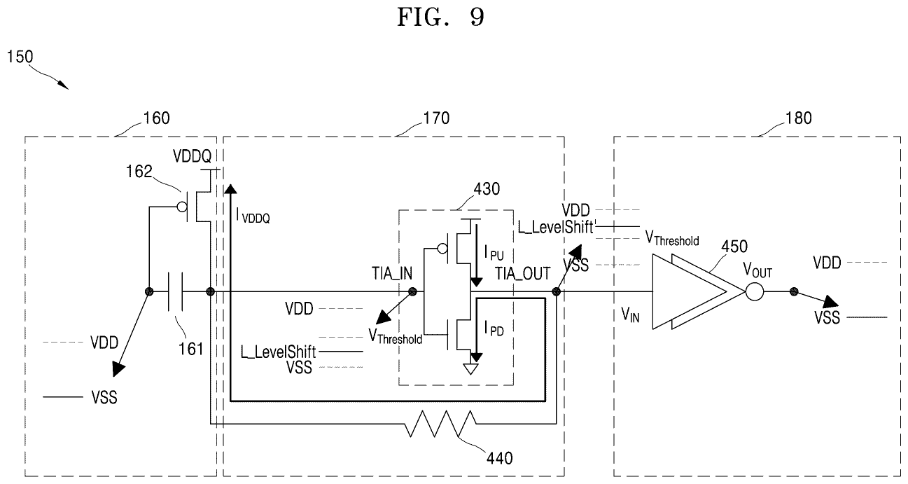

FIG. 9 is a diagram illustrating a driving type of a bus circuit (e.g., the bus circuit 130 illustrated in FIG. 4) according to an embodiment.

In the bus circuit 130 according to an embodiment, when the ground voltage VSS is applied to the level shifter 160, the level shifter 160 may output a first low-level shift voltage L_LevelShift. When the ground voltage VSS is applied to the level shifter 160, the receiving terminal 150 may output the ground voltage VSS.

The ground voltage VSS may be applied to an end of the capacitor 161 and the gate electrode of the PMOS 162 in the level shifter 160. When the ground voltage VSS is applied to the gate electrode of the PMOS 162, the voltage level of the source electrode and the voltage level of the gate electrode of the PMOS 162 may be different from each other. When the voltage level of the source electrode and the voltage level of the gate electrode of the PMOS 162 are different from each other, the PMOS 162 may be turned on.

When the PMOS 162 is turned on, a current I_{PU} may flow through an upper transistor in the first inverter 430 of the receiving terminal 150. When the PMOS 162 is turned on, a current I_{PD} may flow through a lower transistor in the first inverter 430 of the receiving terminal 150. Based on the current I_{PU} flowing through the upper transistor in the first inverter 430 and the current I_{PD} flowing through the lower transistor in the first inverter 430, a voltage of the TIA input node TIA_IN may be set as a first low-level shift voltage L_LevelShift. The TIA input node TIA_IN may be located between the other end of the capacitor 161 and an input terminal of the first inverter 430. The level shifter 160 may output the first low-level shift voltage L_LevelShift.

The first inverter 430 of the receiving terminal 150 may receive the first low-level shift voltage L_LevelShift, i.e., the voltage of the TIA input node TIA_IN. The first inverter 430 may set the voltage of the TIA output node TIA_OUT as a second low-level shift voltage L_LevelShift′. The TIA output node TIA_OUT may be arranged between the first inverter 430 and the second inverter 450 that is included in the inverter buffer 180. The second inverter 450 may receive the voltage of the TIA output node TIA_OUT as the input voltage V_{IN}. The second inverter 450 may output the ground voltage VSS as the output voltage V_{OUT}.

When the ground voltage VSS is applied, the level shifter 160 according to an embodiment may convert the PMOS 162 to a turn-on state. When the PMOS 162 is converted to the turn-on state, the voltage of the TIA input node TIA_IN and the voltage of the TIA output node TIA_OUT may be set as a voltage which satisfies that the current I_{PU} flowing through the upper transistor of the first inverter 430 is a sum of the current I_{PD} flowing through the lower transistor and a current flowing through the supply voltage terminal.

When it is assumed that the voltage of the TIA input node TIA_IN is greater than the high-level shift voltage H_LevelShift set in FIG. 7, at the same time when the current flows from the TIA input node TIA_IN toward the supply voltage terminal, strength of the transistors may be greater than strength of the PMOS 162. Accordingly, the voltage of the TIA output node TIA_OUT becomes lower than the high-level shift voltage H_LevelShift, and a contradiction that the current flows from the TIA input node TIA_IN to the TIA output node TIA_OUT occurs.

Accordingly, the voltage of the TIA input node TIA_IN is set lower than the high-level shift voltage H_LevelShift set in FIG. 7. Accordingly, the current I_{PU} flowing through the upper transistor in the first inverter 430 and the current I_{PD} flowing through the lower transistor in the first inverter 430 flow in a direction marked in FIG. 9. Due to the current I_{PU} flowing through the upper transistor in the first inverter 430 and the current I_{PD} flowing through the lower transistor IPD, the voltage of the TIA output node TIA_OUT may be set greater than the high-level shift voltage H_LevelShift set in FIG. 7. The voltage of the TIA output node TIA_OUT may flow through the second inverter 450 and be output as the output voltage V_{OUT} in the form of the ground voltage VSS.

Collectively referring to FIGS. 4, 7, 8, and 9, the bus circuit 130 according to an embodiment may set the voltage of the receiving terminal 150 by using the level shifter 160.

In prior documents, a receiving circuit, by which a signal swinging with reference to a ground voltage (0V) may be efficiently received at a receiving terminal, has been devised. In prior documents, when a small signal close to the ground voltage (0V) is received, a level shift operation was performed through a common gate amplifier circuit. However, there was a trade-off relationship between the gain and the voltage headroom determined by a resistor of the common gate amplifier circuit.

A characteristic that an operation area of the PMOS 162 varies according to a voltage input to the gate terminal of the PMOS 162, i.e., a voltage output from the transmitting terminal 140, was used in the level shifter 160 of the bus circuit 130 according to an embodiment. The level shifter 160 according to an embodiment is based on change in the input voltage of the TIA at a back end, and thus may be free from the issue of voltage headroom.

In the level shifter 160 according to an embodiment, two terminals of the capacitor 161 may be respectively connected to the gate electrode and the drain electrode of the PMOS 162. While a voltage of an output voltage of the transmitting terminal 140 changes from the ground voltage (0V) to the supply voltage VDDQ, a level of an operation voltage of the TIA 170 may be about 0.5*VDD. The level shifter 160 according to an embodiment may be configured to prevent flow of a direct current between the transmitting terminal 140 and the TIA 170, due to a difference between the level of the output voltage of the transmitting terminal 140 and the level of the operation voltage of the TIA 170.

The level shifter 160 according to an embodiment may be configured to enable the voltages at the two terminals of the capacitor 161 to be set different from each other. The level shifter 160 according to an embodiment may be configured to change the input voltage of the TIA 170 through the PMOS 162. The level shifter 160 according to an embodiment may be configured to determine the input voltage of the TIA 170 regardless of the voltage of the transmitting terminal 140.

The bus circuit 130 according to an embodiment may have low input impedance. The bus circuit 130 according to an embodiment may be configured to maintain a high bandwidth of the receiving terminal 150.

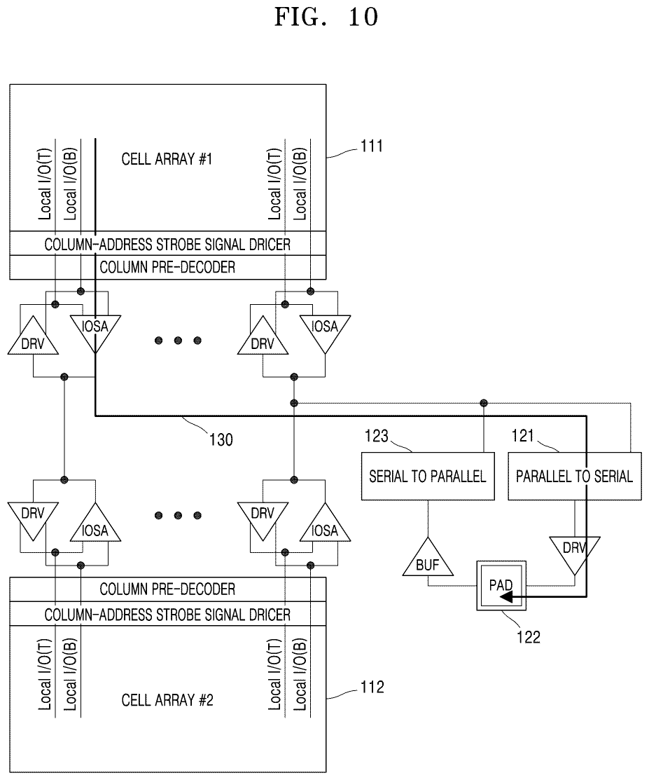

FIG. 10 is a diagram illustrating a type of application of a memory circuit (e.g., the memory circuit 100 illustrated in FIG. 1) according to an embodiment.

The memory circuit 100 according to an embodiment 100 may include the bus circuit 130. The bus circuit 130 may include a global bus line connecting a plurality of cell arrays 111 and 112 to a pad 122 through a parallel-to-serial converter 121.

The plurality of cell arrays 111 and 112 may be memory units included in a memory cell (e.g., the memory cell 110 in FIG. 1). The parallel-to-serial converter 121 may be an interface (e.g., the interface 120 in FIG. 1) to connect the plurality of cell arrays 111 and 112 to the pad 122. The pad 122 may be a connector to electrically connect the memory circuit 100 to other components of the electronic device. The global bus line may be a circuit included in a circuit requiring a high bandwidth in the bus circuit 130, e.g., an integrated circuit, a digital circuit, and a dynamic random access memory (DRAM) circuit.

The memory circuit 100 according to an embodiment may have a group of DRAM products (e.g.: GDDR and DDR) configured to transceive data through the global bus line as a target or an application. To increase the bandwidth, which is the most important performance of DRAM, it is required to increase the number of global bus lines or increase a data transmission rate of a single global bus line. It is not easy to increase the number of global bus lines in a DRAM having a limited capacity. The memory circuit 100 according to an embodiment is intended to suggest a technology of increasing a data transmission rate of a single global line.

More particularly, in a case of TIA in which a resistive feedback is used for an inverter, a bandwidth of a transceiving circuit may be increased by reducing power consumption. As reduction in power consumption is emphasized in a DRAM, the supply voltage VDDQ having the level lower than the level of the reference voltage VDD may be applied to a receiving terminal of the DRAM in which low power is considered important.

However, this is not easily applied to an on-chip global bus line of the DRAM product that is targeted. Because a complicated transceiver circuit structure was necessary in related arts and researches when applying an inverter-based TIA. Accordingly, it was not appropriate to directly apply a structure of inverter-based TIA to an on-chip global bus line having a small physical size and a small area.

In addition, in case of applying the supply voltage VDDQ having the level lower than the level of the reference voltage VDD, it was not easy to satisfy a bandwidth required for the on-chip global bus line.

The bus circuit 130 according to an embodiment includes the level shifter 160 including the capacitor 161 and the PMOS 162. The bus circuit 130 according to an embodiment may simultaneously use advantages of two types of technologies, i.e., the inverter-based TIA and the supply voltage VDDQ having the level lower than the level of the reference voltage VDD. By using the bus circuit 130 according to an embodiment, the bandwidth in the on-chip global bus line may be increased. The bus circuit 130 according to an embodiment may be implemented through the capacitor 161 and the PMOS 162 without complicated circuits, and therefore may be easily applied within a limited size (area) of a DRAM product to which the memory circuit 100 according to an embodiment is applied.

Provided is a method of further improving the performance of transceiving the signals while using a low-level supply voltage and maintaining a simple structure of the circuit.

According to an aspect of the disclosure, a memory circuit includes a memory cell; an interface; and a bus circuit connecting the memory cell and the interface to each other, wherein the bus circuit may include a receiving terminal; and a transmitting terminal, the receiving terminal may include a level shifter including a capacitor and a PMOS; and a TIA, wherein the level shifter may decrease a supply voltage of the transmitting terminal to below a reference voltage by outputting a first voltage that is set based on a size of at least one transistor included in the TIA by turning off the PMOS in a first mode and outputting a second voltage set according to a current introduced from the TIA by turning on the PMOS in a second mode.

In an embodiment, the transmitting terminal may include a first transistor and a second transistor connected to the first transistor, and the level shifter may be connected, through a channel, to a point at which the first transistor and the second transistor are connected to each other.

In an embodiment, the TIA may include a first inverter; and a resistor arranged in parallel to the first inverter, and the receiving terminal may include an inverter buffer connected to the TIA.

In an embodiment, a first electrode of the capacitor may be connected to the channel, a second electrode of the capacitor may be connected to the TIA, a gate electrode of the PMOS may be connected to the first electrode of the capacitor, and the drain electrode of the PMOS may be connected to the second electrode of the capacitor.

In an embodiment, the TIA may output a ground voltage when a first path connected to a ground of the transmitting terminal is activated.

In an embodiment, the TIA may output a supply voltage when a second path connected to a supply voltage terminal of the transmitting terminal is activated.

In an embodiment, parasitic capacitance may be generated at the transmitting terminal, based on driving of the TIA.

In an embodiment, when a supply voltage at a level lower than a level of the reference voltage is applied to the level shifter, the level shifter may output a high-level shift voltage, and the receiving terminal may output the reference voltage.

In an embodiment, an input voltage and an output voltage of the receiving terminal may be in inverse proportion.

In an embodiment, when a ground voltage is applied to the level shifter, the level shifter may output a low-level shift voltage, and the receiving terminal may output the ground voltage.

In an embodiment, the bus circuit may further include a global bus line connecting a plurality of cell arrays to a pad through a parallel-to-serial converter.

According to another aspect of the disclosure, a driving method of a memory circuit, the memory circuit including a memory cell, an interface, and a bus circuit connecting the memory cell and the interface, wherein the bus circuit may include a receiving terminal and a transmitting terminal, wherein the transmitting terminal may include a level shifter and a trans-impedance amplifier (TIA), and wherein the level shifter may include a capacitor and a positive channel metal-oxide semiconductor (PMOS), the method may include decreasing, by the level shifter, a supply voltage of the transmitting terminal to below a reference voltage by outputting a first voltage set according to a size of at least one transistor included in the TIA by turning off the PMOS in a first mode and outputting a second voltage set according to a current introduced from the TIA by turning on the PMOS in a second mode.

In an embodiment, connecting of the TIA may include outputting a ground voltage by the TIA, when a first path connected to a ground of the transmitting terminal is activated.

In an embodiment, connecting of the TIA may include outputting a supply voltage, by the TIA, when a second path connected to a supply voltage of the transmitting terminal is activated.

In an embodiment, connecting of the TIA may include generating parasitic capacitance at the transmitting terminal based on driving of the TIA.

In an embodiment, the decreasing of the supply voltage to below the reference voltage by the level shifter may include, when a supply voltage at a level lower than a level of the reference voltage is applied to the level shifter, outputting a high-level shift voltage by the level shifter and outputting the reference voltage by the receiving terminal.

In an embodiment, an input voltage and an output voltage of the receiving terminal may be in inverse proportion.

In an embodiment, the decreasing of the supply voltage to below the reference voltage by the level shifter may include outputting a low-level shift voltage by the level shifter and outputting a ground voltage by the receiving terminal when the ground voltage is applied to the level shifter.

According to the disclosure, a low-level supply voltage may be used, a structure of a circuit may be maintained simple, and the performance of transceiving a signal by a memory circuit may be improved.

A method according to an embodiment may be implemented in the form of a program command executable through various computer units and written in a computer-readable medium. The computer-readable medium may individually or collectively include a program command, a data file, a data structure, and the like. The program command written in the medium may be particularly designed and configured for the disclosure and may be known and available to those skilled in the art of computer software. Examples of the computer-readable recording medium includes magnetic media such as hard disks, floppy disks, and magnetic tapes, optical media such as compact disc read-only memory (CD-ROM) and digital versatile disc (DVD), magneto-optical media such as floptical disks, and hardware devices particularly configured to store and execute program commands, e.g., read-only memory (ROM), random access memory (RAM), and flash memories. Examples of computer commands may include not only machine language codes created by a compiler, but also high-level languages codes that may be executed by a computer using an interpreter and the like.

Some embodiments may also be implemented in the form of a recording medium including computer-executable instructions, e.g., a program module executed by a computer. The computer-readable medium may include any available medium that may be accessed by a computer, and encompass volatile media, non-volatile media, detachable media, and undetachable media. In addition, the computer-readable medium may include both of a computer storage medium and a communication medium. Computer storage medium may include all of a volatile medium, a non-volatile medium, a detachable medium, and an undetachable medium implemented through arbitrary methods or technologies for storing information such as computer-readable instructions, data structures, program modules, or other data. Communication medium may include computer readable instructions, data structures, other data in non-transitory data signals, such as program modules. In addition, some embodiments may also be implemented as computer programs or computer program products including computer-executable instructions, e.g., computer programs executed by a computer.

A device-readable storage medium may be provided in the form of a non-transitory storage medium. Here, ‘non-transitory storage medium’ only indicates that the medium is a tangible device and does not include signals (e.g., electromagnetic waves), and is not intended to distinguish a case where data is semi-permanently stored in the storage medium and a case where data is temporarily stored in the storage medium. For example, ‘non-transitory storage medium’may include a buffer in which data is temporarily stored.

According to an embodiment, the method according to various embodiments disclosed herein may be provided in computer program products. Computer program products may be traded as products between sellers and consumers. Computer program products may be distributed in the form of device-readable storage media (e.g.: compact disc read-only memory (CD-ROM)) or may be distributed (e.g.: downloaded or uploaded) directly or online through application stores or between two user devices (e.g.: smartphones). In case of online distribution, at least some of computer program products (e.g.: downloadable apps) may be temporarily stored or temporarily generated in device-readable storage media such as servers of manufacturers, servers of application stores, or memories of proxy servers.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A memory circuit comprising:
a memory cell;
an interface; and
a bus circuit connecting the memory cell and the interface to each other, wherein
the bus circuit comprises:
a receiving terminal; and
a transmitting terminal, wherein
the receiving terminal comprises:
a level shifter comprising a capacitor and a positive channel metal-oxide semiconductor (PMOS); and
a trans-impedance amplifier (TIA), wherein
the level shifter decreases a supply voltage of the transmitting terminal to below a reference voltage by outputting a first voltage that is set based on a size of at least one transistor included in the TIA by turning off the PMOS in a first mode and outputting a second voltage set according to a current introduced from the TIA by turning on the PMOS in a second mode.

2. The memory circuit of claim 1, wherein
the transmitting terminal comprises a first transistor and a second transistor connected to the first transistor, and
the level shifter is connected, through a channel, to a point at which the first transistor and the second transistor are connected to each other.

3. The memory circuit of claim 1, wherein
the TIA comprises
a first inverter; and
a resistor arranged in parallel to the first inverter, and
the receiving terminal comprises
an inverter buffer connected to the TIA.

4. The memory circuit of claim 2, wherein
a first electrode of the capacitor is connected to the channel,
a second electrode of the capacitor is connected to the TIA,
a gate electrode of the PMOS is connected to the first electrode of the capacitor, and
a drain electrode of the PMOS is connected to the second electrode of the capacitor.

5. The memory circuit of claim 1, wherein
the TIA outputs a ground voltage when a first path connected to a ground of the transmitting terminal is activated.

6. The memory circuit of claim 1, wherein
the TIA outputs a supply voltage when a second path connected to a supply voltage terminal of the transmitting terminal is activated.

7. The memory circuit of claim 1, wherein
parasitic capacitance is generated at the transmitting terminal, based on driving of the TIA.

8. The memory circuit of claim 1, wherein,
when a supply voltage at a level lower than a level of the reference voltage is applied to the level shifter,
the level shifter outputs a high-level shift voltage, and
the receiving terminal outputs the reference voltage.

9. The memory circuit of claim 1, wherein
an input voltage and an output voltage of the receiving terminal are in inverse proportion.

10. The memory circuit of claim 1, wherein,
when a ground voltage is applied to the level shifter,
the level shifter outputs a low-level shift voltage, and
the receiving terminal outputs the ground voltage.

11. The memory circuit of claim 11, wherein
the bus circuit further comprises a global bus line connecting a plurality of cell arrays to a pad through a parallel-to-serial converter.

12. A method of driving a memory circuit, wherein the memory circuit comprises a memory cell, an interface, and a bus circuit connecting the memory cell and the interface, wherein the bus circuit comprises a receiving terminal and a transmitting terminal, wherein the receiving terminal comprises a level shifter and a trans-impedance amplifier (TIA), and wherein the level shifter comprises a capacitor and a positive-channel metal-oxide semiconductor (PMOS), the method comprising:
decreasing, by the level shifter, a supply voltage of the transmitting terminal to below a reference voltage by outputting a first voltage set according to a size of at least one transistor included in the TIA by turning off the PMOS in a first mode and outputting a second voltage set according to a current introduced from the TIA by turning on the PMOS in a second mode.

13. The method of claim 12, wherein
connecting of the TIA comprises outputting a ground voltage, by the TIA, when a first path connected to a ground of the transmitting terminal is activated.

14. The method of claim 12, wherein
connecting of the TIA comprises outputting a supply voltage, by the TIA, when a second path connected to a supply voltage terminal of the transmitting terminal is activated.

15. The method of claim 12, wherein
connecting of the TIA comprises generating parasitic capacitance at the transmitting terminal, based on driving of the TIA.

16. The method of claim 12, wherein
the decreasing of the supply voltage to below the reference voltage by the level shifter comprises,
when the supply voltage at a level lower than a level of the reference voltage is applied to the level shifter:
outputting a high-level shift voltage by the level shifter; and
outputting the reference voltage by the receiving terminal.

17. The method of claim 12, wherein an input voltage and an output voltage of the receiving terminal are in inverse proportion.

18. The method of claim 12, wherein,
the decreasing of the supply voltage to below the reference voltage by the level shifter comprises,
when a ground voltage is applied to the level shifter:
outputting a low-level shift voltage by the level shifter; and
outputting the ground voltage by the receiving terminal.
